(19) United States
(12) Patent Application Publication
(10) Pub. No.: US 2026/0002912 A1
(43) Pub. Date: Jan. 1, 2026

(54) METHOD FOR FABRICATING AN ENCLOSURE OF A PHOTOACOUSTIC DETECTING DEVICE

(71) Applicant: COMMISSARIAT A L'ENERGIE ATOMIQUE ET AUX ENERGIES ALTERNATIVES, Paris (FR)

(72) Inventors: Toufiq BRIA, Grenoble cedex 09 (FR); Kévin JOURDE, Grenoble cedex 09 (FR); Sébastien BARNOLA, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/255,834

(22) Filed: Jun. 30, 2025

(30) Foreign Application Priority Data
Jun. 30, 2024 (FR) FR2407122

(51) Int. Cl. G01N 29/24; B81C 1/00; G01N 29/02; G01N 29/04

(52) U.S. Cl. CPC G01N 29/2418; B81C 1/00539; G01N 29/02; G01N 29/04; B81C 2201/0133

(57) ABSTRACT

Method for fabricating an enclosure (2) bounding a cavity (4), the enclosure being intended to be applied against a sample to be analysed (E), the cavity being configured to extend between the sample and an acoustic transducer (T), the cavity opening onto a contact face (3) intended to be applied against the sample, the enclosure comprising:
a contact aperture (3o) formed in the contact face, and opening into the cavity;
a membrane (5) extending through the cavity, facing the contact face, so that all or part of the cavity lies between the membrane and a cover (2c);
   wherein the method comprises the steps of microstructuring three substrates, so as to form the cover, the rear portion of the cavity, the membrane and the front portion of the cavity.

### TECHNICAL FIELD

The technical field of the invention is fabrication of a device for detecting an analyte via the photoacoustic effect. Fabrication is carried out using the type of wafer-level microfabrication steps applied to substrates in the field of microelectronics.

### PRIOR ART

Photoacoustic detection is based on the detection of an acoustic wave generated under the effect of absorption, by an analysed medium, of a pulsed or amplitude-modulated incident electromagnetic wave. The acoustic wave is formed following heating of molecules of interest present in the analysed medium, under the effect of absorption of the incident wave. The heating causes modulated thermal expansion of the medium, the acoustic wave resulting from the thermal expansion.

The photoacoustic detection may be focused on one particular analyte by adjusting the wavelength of the incident electromagnetic wave to an absorption wavelength of the analyte. Photoacoustic detection has thus been applied to detect gaseous species in a gas, or to detect the presence of particular molecules in biological tissues. The wavelength of the incident wave is frequently located in the infrared.

Photoacoustic detection is thus a non-invasive analysis technique able to be implemented in scattering or opaque media.

U.S. Pat. No. 11,774,347 describes a photoacoustic detecting device comprising an enclosure intended to be applied against a sample to be analysed. The enclosure bounds a cavity, opening onto a contact face, the latter being configured to be placed in contact with the sample. In the enclosure the device comprises a membrane that is intended to retain moisture and transmit a photoacoustic wave emitted by the sample.

U.S. Pat. No. 11,674,931 describes a photoacoustic detecting device comprising an enclosure intended to be applied against a sample to be analysed. The enclosure bounds a cavity, opening onto a contact face, the latter being configured to be placed in contact with the sample. The device comprises a tube extending from the cavity to outside the cavity. The tube forms a vent of the device. The dimensions of the tube are tailored to the volume of the cavity, so as to optimise the performance of the device.

The inventors provide a method for fabricating a device having features such as described in U.S. Pat. Nos. 11,774,347 and/or 11,674,931, using wafer-level microfabrication methods. The method described below allows a detecting device employing the photoacoustic effect to be obtained in a straightforward manner, by taking advantage of the ability of the techniques of microelectronics to produce a high number of devices simultaneously.

### SUMMARY OF THE INVENTION

A first subject of the invention is a method for fabricating an enclosure bounding a cavity, preferably a hollow cavity, the enclosure being intended to be applied against a sample to be analysed, the cavity being configured to extend between the sample and an acoustic transducer, the cavity opening onto a contact face intended to be applied against the sample, the enclosure comprising:
a contact aperture formed in the contact face, and opening into the cavity;
a membrane extending through the cavity, facing the contact face, so that all or part of the cavity lies between the membrane and a cover;

Wherein the method comprises the following steps:
1) microstructuring a first substrate, so as to form the cover;
2) microstructuring a second substrate, so as to form a rear portion of the enclosure, bounding all or part of the cavity, between the membrane and the cover;
3) microstructuring a third substrate, so as to form a front portion of the enclosure, comprising the membrane;
4) assembling the cover with the rear portion of the enclosure, and assembling the rear portion of the enclosure with the front portion of the enclosure.

According to one possibility, the membrane divides the cavity into a rear portion of the cavity and into a front portion of the cavity, the front portion of the cavity opening onto the contact face, the membrane being placed between the front portion of the cavity and the rear portion of the cavity. Preferably, the front portion and the rear portion of the cavity are hollow.

Step 2) may comprise forming the rear portion of the cavity.

Step 3) may comprise forming the front portion of the cavity.

Step 1) may comprise forming an acoustic channel through the cover, the acoustic channel being intended to connect the cavity to the acoustic transducer.

Step 1) may comprise forming a vent through the cover, the vent being intended to connect the cavity to a medium outside the latter.

Step 1) may comprise forming a detection channel through the cover, the detection channel being intended to connect the cavity to a temperature and/or humidity sensor.

According to one possibility:
the first substrate comprises a first upper layer, an insulating first intermediate layer, and a first lower layer;
step 1) comprises.
   1i) etching the first lower layer to form at least one first lower aperture, the first intermediate layer acting as etch-stop layer;
   1ii) etching the first upper layer to form at least one first upper aperture, the first intermediate layer acting as etch-stop layer;
   1iii) removing the first intermediate layer, between each first lower aperture formed in substep 1i) and each first upper aperture formed in substep 1ii), respectively, so as to form a channel chosen from the acoustic channel, the vent or the detection channel.

Preferably, in steps 1i) and 1ii), at least two or three lower apertures and at least two or three upper apertures are formed, so as to form two or three channels, in step 1iii), each channel corresponding to a channel chosen from the acoustic channel, the vent or the detection channel.

The first intermediate layer may be formed from an insulator, the first upper layer and the first lower layer being formed from a semiconductor.

According to one possibility:
the second substrate comprises a second upper layer, a second intermediate layer, and a second lower layer;
step 2) comprises the following substeps:
   2i) etching the second upper layer to form a second upper aperture, the second intermediate layer acting as etch-stop layer;
   2ii) etching the second lower layer to form a second lower aperture, the second intermediate layer acting as etch-stop layer;
   2iii) removing the second intermediate layer, between the second upper aperture formed in substep 2i) and the second lower aperture formed in substep 2ii), respectively, so as to form all or part of the cavity.

According to one possibility:
the second substrate lies parallel to a main plane;
in step 2i), the etching is carried out, through the second upper layer, according to an upper dimension, in the main plane;
in step 2ii), the etching is carried out, through the second lower layer, according to a lower dimension, in the main plane;
the lower dimension is greater than the upper dimension.

The thickness of the second lower layer may be greater than the thickness of the second upper layer.

According to one possibility, the second intermediate layer is formed from an insulator, the second upper layer and the second lower layer being formed from a semiconductor.

According to one possibility, in step 2iii), removing the second intermediate layer forms the rear portion of the cavity.

According to one possibility:
the third substrate comprises a third upper layer, a third intermediate layer, and a third lower layer;
step 3) comprises:
   3i) etching the third lower layer, so as to form a front portion of the enclosure, the third intermediate layer acting as etch-stop layer, the third upper layer forming the membrane.

In step 3i), etching the third lower layer may form the front portion of the cavity.

According to one possibility, the membrane is passed through by apertures. The method may then comprise:
3ii) etching the third upper layer, the third intermediate layer acting as etch-stop layer, the etching of the third upper layer being configured to form a plurality of third apertures extending through the third upper layer;
3iii) removing the third intermediate layer, level with each third aperture resulting from substep 3ii), so that each third aperture is a through-aperture.

According to one possibility, each assemblage is carried out by thermocompression bonding.

A second subject of the invention is an enclosure bounding a cavity, the enclosure being intended to be applied against a sample to be analysed, the cavity being configured to extend between the sample and an acoustic detector, the cavity opening onto a contact face intended to be applied against the sample, the enclosure comprising:
a contact aperture formed in the contact face, and opening into the cavity;
a membrane extending through the cavity, facing the contact face, so that all or part of the cavity lies between the membrane and a cover;
   the enclosure being fabricated by implementing steps 1) to 4) of the first subject of the invention.

A third subject of the invention is a device comprising an enclosure, bounding a cavity, the enclosure being configured to be applied against a sample to be analysed, the device comprising:
a contact face that opens into the cavity, and that is intended to be applied against the sample;
a light source, configured to emit pulsed or amplitude-modulated light through the enclosure, towards the contact face;
an acoustic transducer, connected to the cavity;
wherein the enclosure is an enclosure according to the second subject of the invention.

The invention will be better understood on reading the description of the examples of embodiment presented, in the remainder of the description, with reference to the figures listed below.

### FIGURES

FIG. 1 shows a view of a complete photoacoustic detecting device.

FIGS. 2A to 2T schematically show steps of processing of a first substrate intended to form a cover of the device.

FIGS. 3A to 3Q schematically show steps of processing of a second substrate intended to form a rear portion of an enclosure of the device.

FIGS. 4A to 4K schematically show steps of processing of a third substrate intended to form a front portion of an enclosure of the device.

FIGS. 5A to 5D show the steps of assemblage of the first substrate, of the second substrate and of the third substrate after they have been processed.

### DESCRIPTION OF PARTICULAR EMBODIMENTS

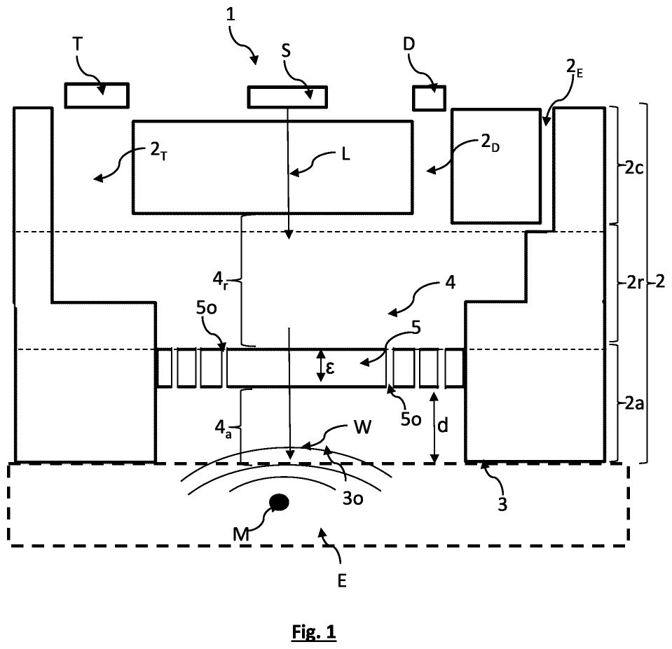

FIG. 1 schematically shows a device 1 allowing the invention to be implemented. The device 1 is configured to be applied against a sample E to be analysed. The device comprises a contact face 3 intended to be applied against the sample to be analysed. The contact face is designed to conform to the sample E against which it is intended to be pressed. For example it is planar.

In this example, the sample E is the skin of a user. The device comprises a light source S, configured to emit a light beam L that propagates to the sample E to be analysed. The light source S is pulsed or amplitude modulated. The light beam L is emitted in an emission spectral band Δλ containing an absorption wavelength Na of molecules M present in the sample. One objective of the device 1 is to detect the presence of the molecule M and possibly to estimate a concentration thereof.

The molecule M may for example be glucose, or a bodily analyte such as cholesterol, triglycerides, urea, albumin, alcohol (ethanol for example) or tetrahydrocannabinol.

The emission spectral band Δλ preferably lies in the visible or in the infrared, for example between wavelengths of 3 μm and 15 μm. Preferably, the emission spectral band Δλ is sufficiently narrow for the device 1 to be specific to a single analyte. When the analyte is glucose, the emission spectral band is centred on an absorption wavelength of glucose, for example corresponding to a wave number of 1034 cm⁻¹. The light source S may in particular be a pulsed laser source, for example a wavelength-tunable quantum-cascade laser (QCL). The emission spectral band Δλ is then located in the infrared.

According to other embodiments, the light source S may be an incandescent source, or a light-emitting diode. According to those embodiments, it is preferable for the light source S to be associated with a bandpass filter, to define a sufficiently narrow emission spectral band centred on the absorption wavelength in question. However, it is preferable to use a laser source.

The device comprises a confining enclosure 2 that is placed in contact with the sample E, and that bounds a cavity 4. The cavity 4 opens onto a contact aperture 3o formed in the contact face 3, the contact aperture being intended to be placed facing the sample E, and preferably in contact with the latter. The light beam L propagates to the sample E through the cavity 4 and the contact aperture 3o.

The device comprises a membrane 5 extending through the cavity 4, facing the contact face 3, the membrane preferably being passed through by through-apertures 5o. The membrane 5 separates the cavity 4 into a front portion 4a, comprising the contact face 3, and a rear portion 4r, extending between the membrane 5 and a cover 2c. The cover 2c is placed opposite the membrane 5 and thereby closes the cavity 4.

FIG. 1 shows a segmentation of the enclosure 2 into three components:
the cover 2c;
the rear portion 2r, which confines the rear portion of the cavity 4r;
the front portion 2a, which comprises the membrane 5 and the contact face 3.

According to the method described below, these three components are produced separately and are assembled with one another. In FIG. 1, dashed lines have been used to represent lines of separation between the three components.

The membrane 5 may be as described in U.S. Pat. No. 11,774,347. The membrane 5 lies, inside the cavity 4, at a non-zero distance d from the contact aperture 3o. Specifically, during implementation of the device, it is preferable for the membrane 5 not to make contact with the sample E. Placing the membrane at a distance makes it possible to maintain a layer of air between the contact aperture 3o and the membrane 5. The distance between the membrane and the contact aperture is preferably greater than 200 μm, or 500 μm. The thickness ε of the membrane 5 is preferably between 100 μm and 1 mm, and preferably between 150 μm and 750 μm.

When the membrane 5 comprises through-apertures 5o, the latter are dimensioned to transmit the pressure modulation through the membrane 5, while blocking drops of liquid or dust. The through-apertures 5o allow communication of air between the front portion 4a and the rear portion 4r of the cavity 4. The diameter of the through-apertures 5o is preferably between 10 μm and 50 μm, and preferably between 10 μm and 30 μm.

Under the effect of the presence of a molecule M in the sample E, an acoustic wave W, called the photoacoustic wave, is formed. The photoacoustic wave W is an acoustic wave formed as a result of periodic heating of the medium by the incident light beam L, the latter being pulsed or amplitude modulated. Part of the photoacoustic wave W travels through the cavity 4 and is detected by an acoustic transducer T. The acoustic transducer T is connected to the cavity 4 by an acoustic channel 2_{T} formed in the cover 2_{c}. The acoustic transducer T may be a microphone, having a spectral detection range containing the frequency of the photoacoustic wave. The photoacoustic wave is amplitude modulated at the pulse or amplitude-modulation frequency of the light source. Thus, at the acoustic transducer, the pressure is amplitude modulated.

The device may comprise a detector D, configured to detect a temperature and/or a relative humidity level in the cavity. The detector D is connected to the cavity 4 by a detection channel 2_{D} formed in the cover 2c.

The device may comprise a vent 2_{E}, the vent being formed in the cover 2c and configured to connect the cavity 4 to an exterior medium, ambient air for example. Such a vent is described in U.S. Pat. No. 11,674,931. The vent may have a length between 1 mm and 20 mm, and a diameter between 100 μm and 500 μm.

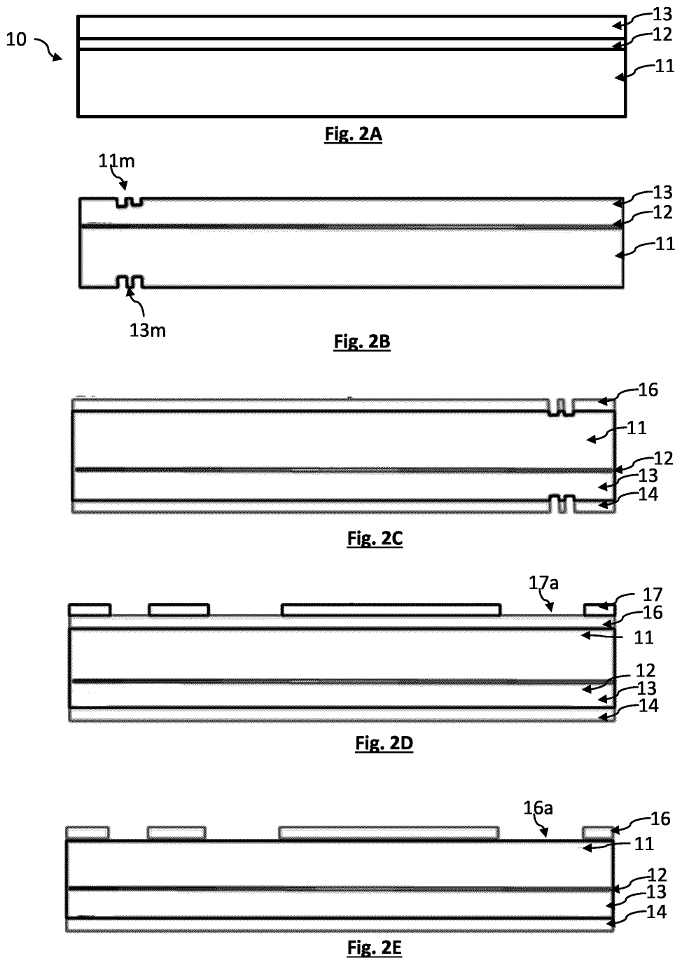

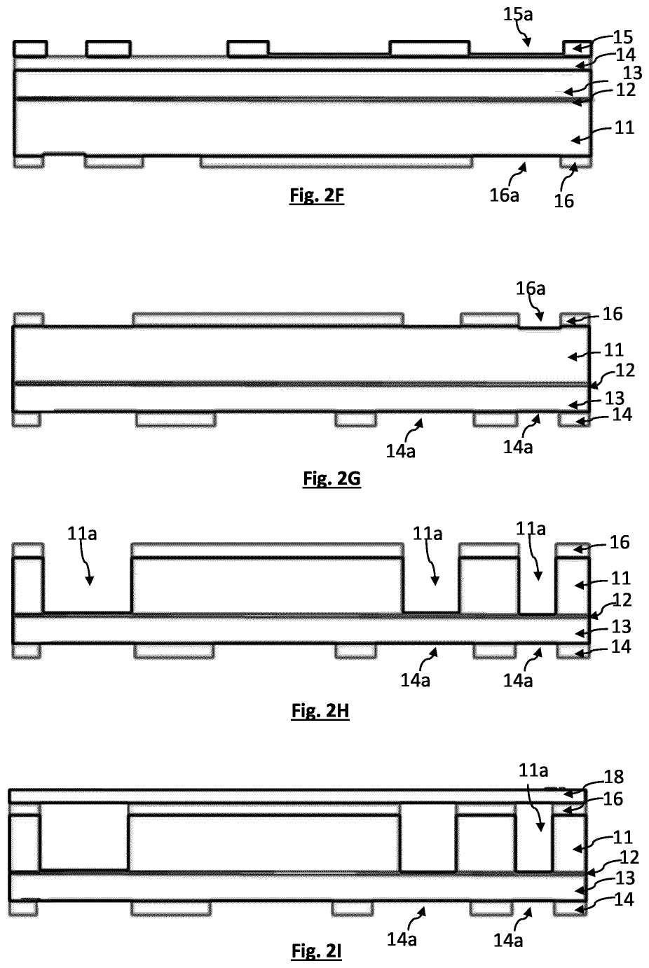

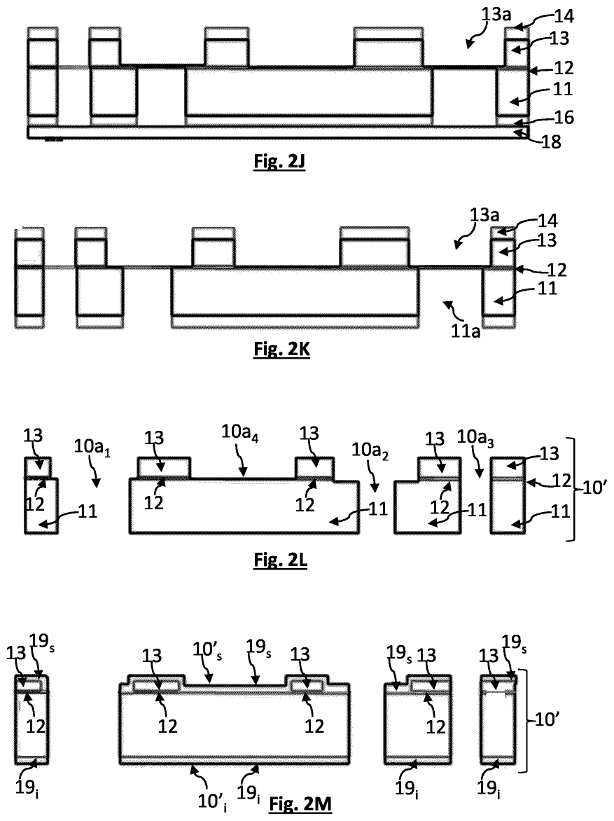

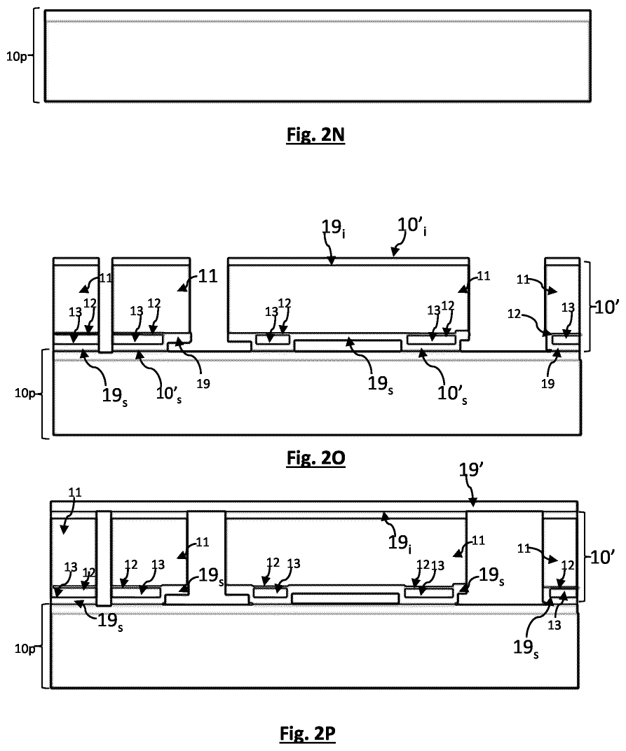

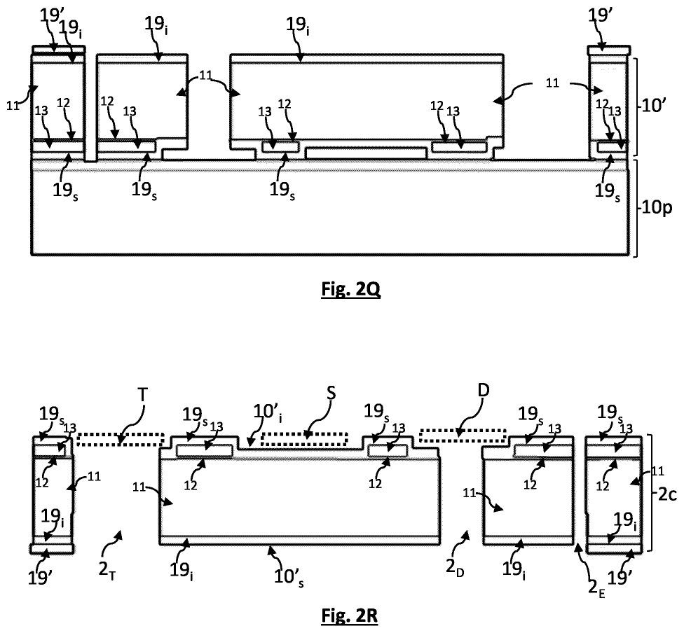

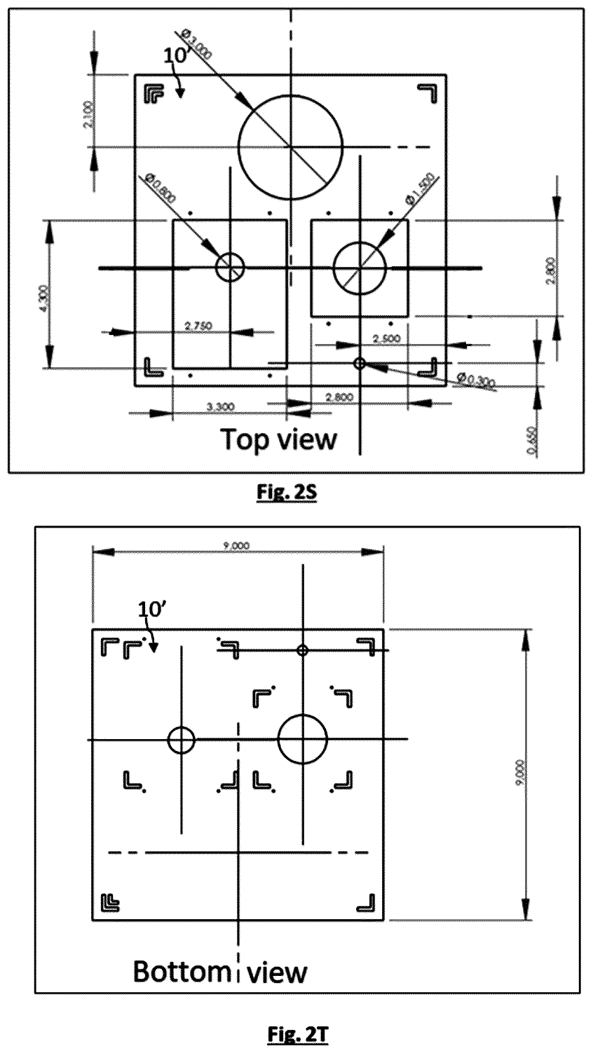

FIGS. 2A to 2R show steps of processing of a first substrate 10, to form the cover 2c of the device. FIG. 2A shows the first substrate, which in this example is an SOI substrate (SOI standing for Silicon-On-Insulator), comprising:
a first lower layer 11, which is a so-called bulk layer, of Si, with a thickness of a few hundred μm, for example of 725 μm, when the diameter of the substrate is 200 mm;
a first intermediate layer 12 of insulator (SiO₂), with a thickness of a few tens of nm or a few μm, for example of 1 or 2 μm;
a first upper layer 13 of silicon, and generally of single-crystal Si, with a thickness of 225 μm.

The steps of structuring of the first substrate 10 are, successively:
Forming marks 11m and 13m on the first lower and upper layers, by laser engraving. See FIG. 2B. These marks form reference points allowing alignment of photolithography masks. These marks have not been shown in the following figures.
Depositing a layer 16 of SiO₂, with a thickness between 3 μm and 5 μm, on the first lower layer 11, and depositing a layer 14 of SiO2, with a thickness between 3 μm and 5 μm, on the first upper layer 13: see FIG. 2C, FIG. 2C being shown after the substrate shown in FIG. 2B has been flipped.

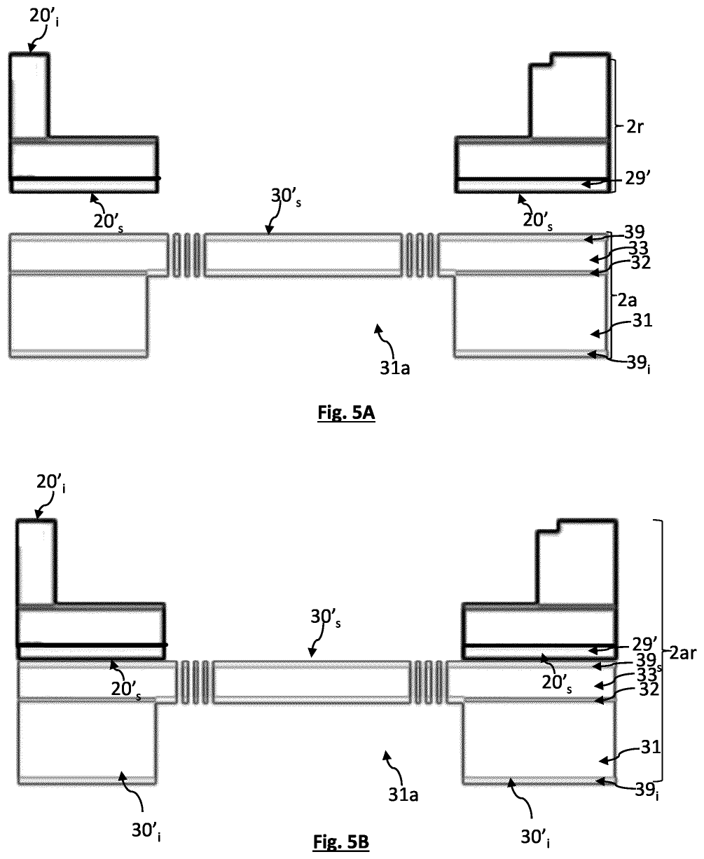

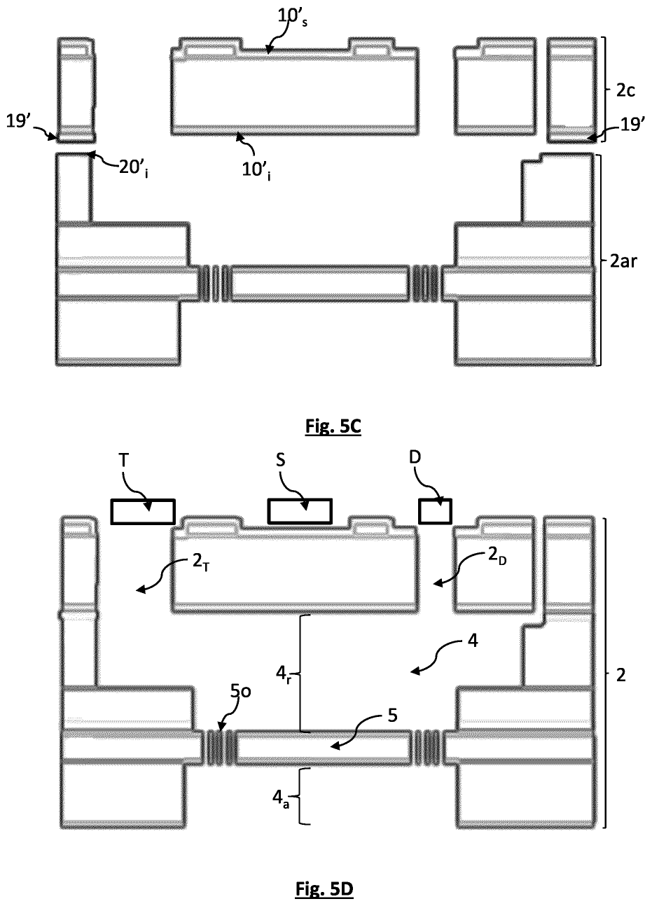

Depositing a layer 17 of photoresist on the layer 16, then forming a pattern through exposure. The pattern defines apertures 17a in the resist layer 17: see FIG. 2D.
Plasma etching the layer 16, so as to form apertures 16a in the layer 16, and removing the resist 17. See FIG. 2E.
Flipping the substrate and depositing a layer 15 of photoresist on the layer 14 of SiO2, then forming a pattern through exposure. The pattern defines apertures 15a in the resist layer 15: see FIG. 2F, in which the substrate has been flipped with respect to FIG. 2E.
Plasma etching the layer 14, so as to form apertures 14a in the layer 14, removing the resist 15 and flipping the substrate. See FIG. 2G.
Plasma etching the first lower layer 11, so as to form first lower apertures 11a in the latter, plumb with each aperture 16a. See FIG. 2H. The first lower apertures 11a are intended to form through-channels, such as the acoustic channel, the detection channel and the vent described above.
Depositing, by lamination, a polymer film 18 (“Revalpha” tape, manufacturer Nitto) on the layer 16, closing the first lower apertures 11a formed in the previous step. See FIG. 2I.
Plasma etching the layer 13 so as to form first upper apertures 13a in the latter, plumb with each aperture 14a resulting from the step described with reference to FIG. 2G. See FIG. 2J, in which the substrate has been flipped with respect to FIG. 2I. During the etching, the polymer film protects a platen on which the first substrate 10 is placed.
Removing the polymer film 18: See FIG. 2K.
Removing, by wet etching, the first intermediate layer 12 of SiO₂, between each first lower aperture 11a and each first upper aperture 13a: see FIG. 2L. This step makes it possible to form 3 through-channels 10a1, 10a2, 10a3, corresponding to the channels 2_{T}, 2_{D}, 2_{E} described with reference to FIG. 1, respectively. A first microstructured substrate 10′ that has the structuring required to form the cover 2c of the device is thus obtained. The first microstructured substrate 10′ extends, thicknesswise, between a first top side 10′ₛ, adjacent to the first upper layer 13, and a first bottom side 10′ᵢ, adjacent to the first lower layer 11.
Depositing a layer 19ₛ, 19ᵢ of Ge—ZnS; this layer having an antireflection function, on the first top and bottom sides 10′ₛ, 10′ᵢ of the substrate 10′. See FIG. 2M. The ZnS has an antireflection function, while the Ge promotes the attachment of ZnS to the Si. Each layer 19ₛ, 19ᵢ is formed with a thickness of 100 nm of Ge and a thickness of 1067 nm of ZnS. The deposition is carried out at 175° C.
A wafer 10p comprising an Si layer with a thickness of 550 μm covered with a layer of a polymer, for example the polymer Revalpha mentioned above, is then used as a handle wafer. Preferably, the polymer used is easily removed with the help of a thermal action.
The wafer is shown in FIG. 2N. The handle will make the substrate handleable, for example allowing it to be placed in and removed from a substrate storage box or carrier.
Affixing the wafer 10p to the first top side 10′ₛ of the substrate 10′: see FIG. 2O, in which the substrate has been flipped with respect to FIG. 2M.
Applying, by lamination, a polymer adhesive film 19′, for example a SINR film (SINR being a registered trademark—supplier Shin-Etsu MicroSi), with a thickness of 12 μm. See FIG. 2P. The assembly thus formed is then annealed.
Exposing the film 19′, so as to leave only a peripheral portion extending around the channels formed in the substrate 10′. FIG. 2Q.
Removing the handle 10p: see FIG. 2R. This step makes it possible to obtain a substrate allowing, after assemblage by thermocompression bonding, the cover 2c of the enclosure 2 of the device to be obtained. The assemblage step is described below, with reference to FIGS. 5A to 5D. Structuring the first substrate 10 makes it possible to create spaces in which the acoustic transducer T, the light source S and the temperature and/or humidity detector D may be placed. These spaces have been shown by dotted lines in FIG. 2R.

FIGS. 2S and 2T show a top and bottom view of the cover 2c, respectively, the cover corresponding to the microstructured substrate 10′.

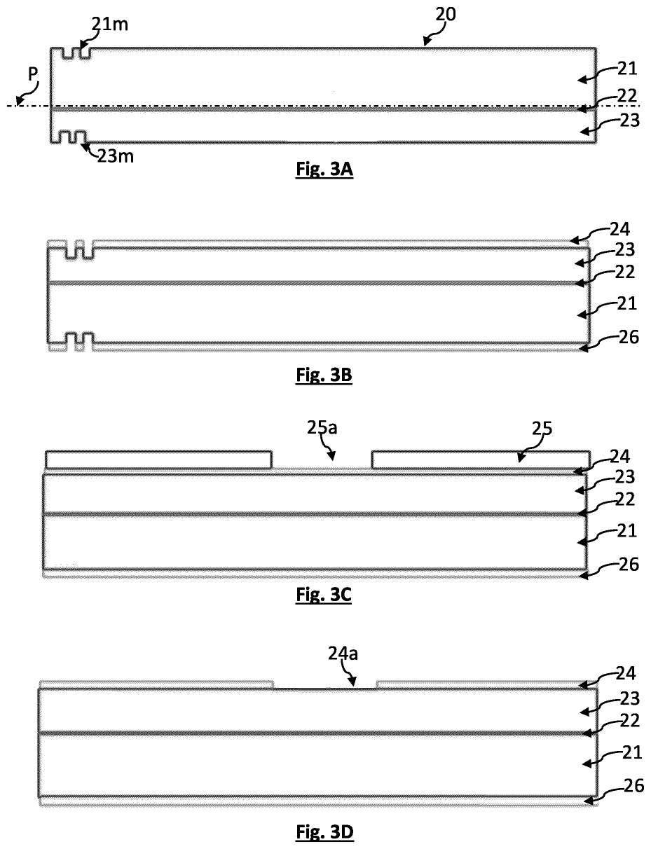

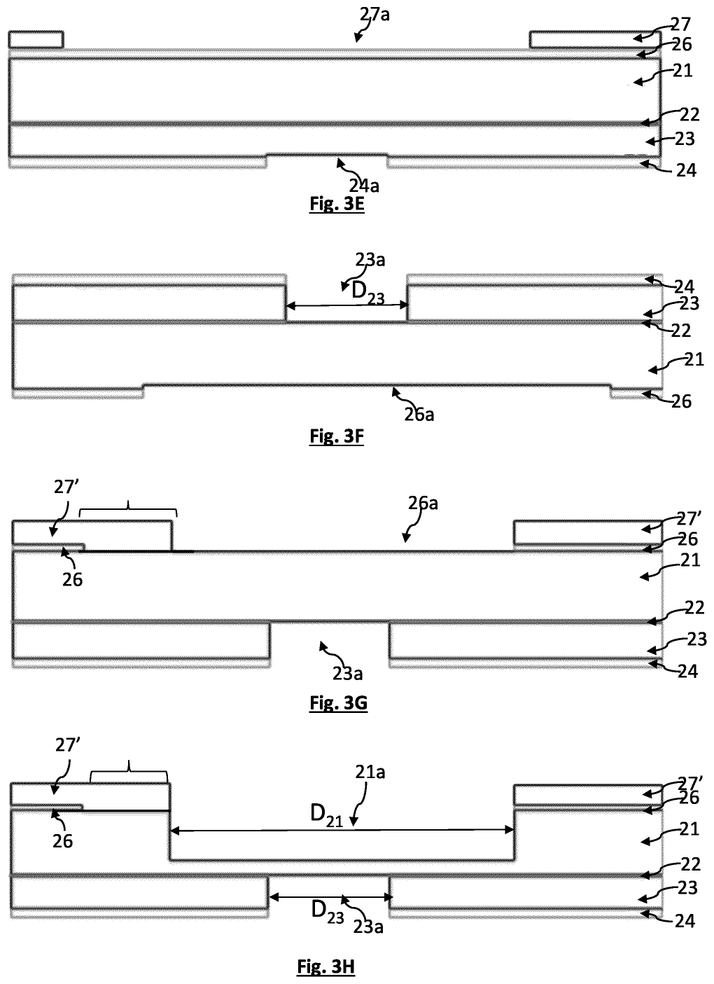

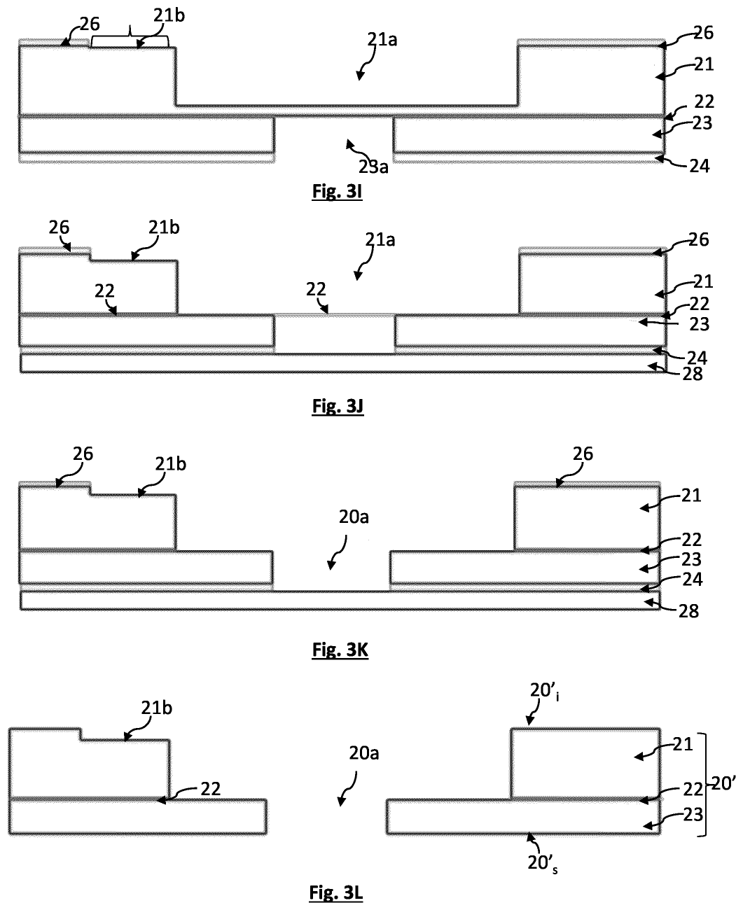

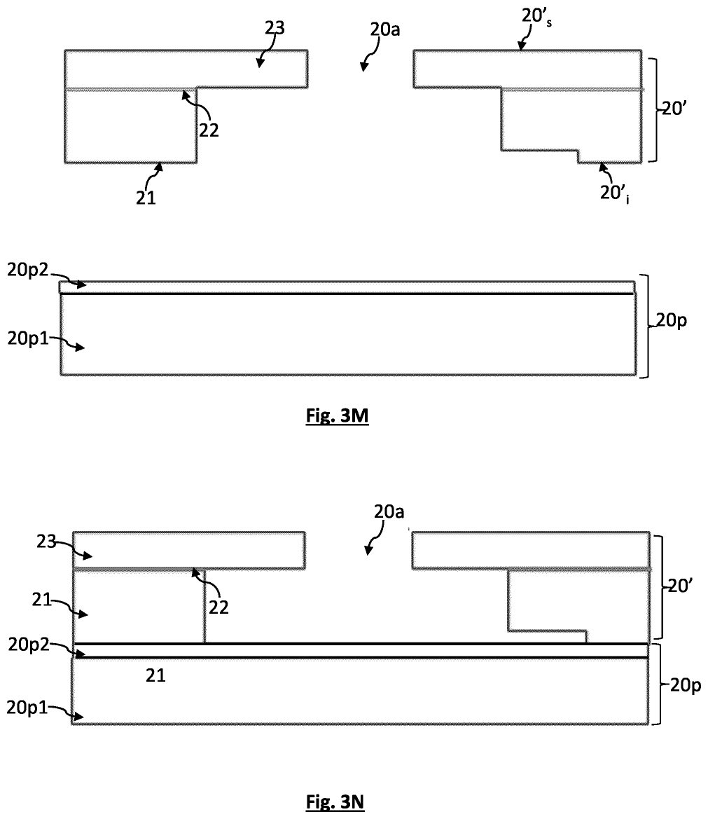

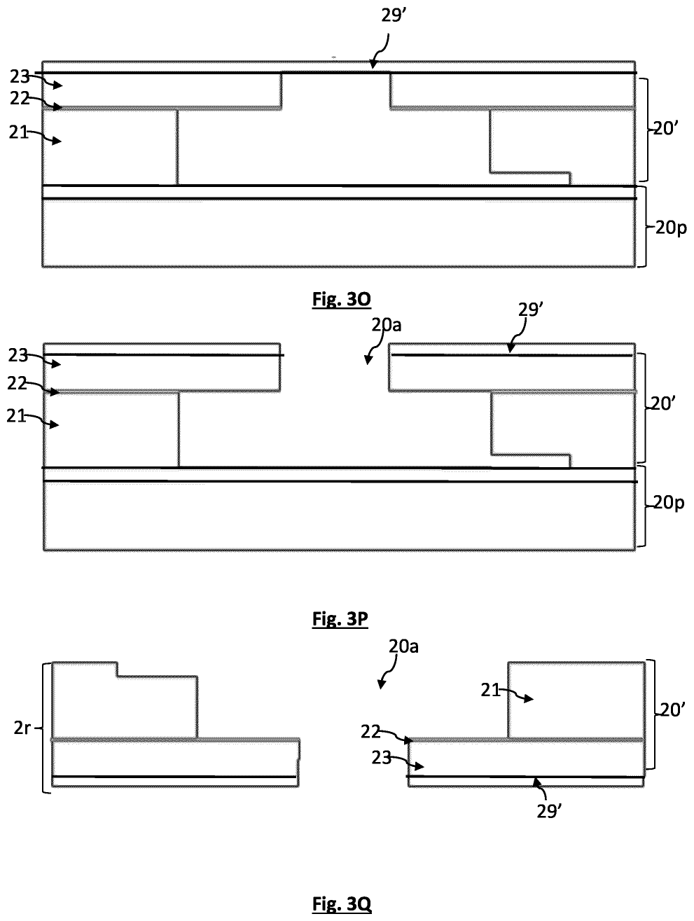

FIGS. 3A to 3Q show the steps of processing of a second substrate 20, to form the rear portion 2r of the enclosure of the device. A second substrate 20 is used, namely an SOI substrate (SOI standing for Silicon-On-Insulator), comprising:
a second lower layer 21, which is a so-called bulk layer, of Si, with a thickness of a few hundred μm, for example of 725 μm, when the diameter of the substrate is 200 mm;
a second intermediate layer 22 of insulator (SiO2), with a thickness of a few tens of nm or a few μm, for example of 1 or 2 μm;
a second upper layer 23 of silicon, and generally of single-crystal Si, with a thickness of 225 μm.

The steps of structuring of the second substrate 20 are, successively:
Forming marks 21m and 23m on the second lower and upper layers, by laser engraving. See FIG. 3A. These marks allow alignment of photolithography masks. These marks are not shown again.
Depositing a layer 26 of SiO₂, with a thickness between 3 μm and 5 μm, on the second lower layer 21, and depositing a layer 24 of SiO₂, with a thickness between 3 μm and 5 μm, on the second upper layer 23: see FIG. 3B, in which the substrate has been flipped with respect to FIG. 3A.
Depositing a layer 25 of photoresist on the layer 24 of SiO₂, then forming a pattern through exposure. The pattern defines an aperture 25a in the resist layer 25: see FIG. 3C.
Plasma etching the layer 24, so as to form an aperture 24a in the layer 24, and removing the resist 25. See FIG. 3D.
Depositing a layer 27 of photoresist on the layer 26, then forming a pattern through exposure. The pattern defines an aperture 27a, larger than the aperture 24a, in the resist layer 27: see FIG. 3E, in which the second substrate has been flipped with respect to FIG. 3D.
Plasma etching the layer 26, so as to form an aperture 26a in the layer 26, then removing the resist 27 and flipping the second substrate and plasma etching the second upper layer 23, so as to form a second upper aperture 23a in the latter, plumb with the aperture 24a resulting from the step described with reference to FIG. 3D. See FIG. 3F, in which the second substrate has been flipped with respect to FIG. 3E. The designation “second upper aperture” designates the fact that it is a question of an aperture formed in the second upper layer 23. Each layer of the second substrate lies in a main plane P, as shown in FIG. 2A. The second upper aperture 23a has, parallel to the main plane, an upper dimension D₂₃.
Depositing a layer 27′ of photoresist on the layer 26 remaining after the etching illustrated in FIG. 3F, some of the resist 27′ covering the first layer 21. The coverage of the layer 21 by the resist 27′ has been indicated by a curly bracket. Exposing the resist 27′, so as to form an aperture 27′a in the layer 27′. See FIG. 3G, in which the second substrate has been flipped with respect to FIG. 3F.
Plasma etching the second lower layer 21 partially, so as to form a second lower aperture 21a in the latter, plumb with the aperture 27′a resulting from the previous step as described above. See FIG. 3H. The apertures 21a and 23a are intended to form the rear portion of the cavity. The designation “second lower aperture” designates the fact that it is a question of an aperture formed in the second lower layer 21. The second lower aperture 21a has, parallel to the main plane, a lower dimension D₂₁. Preferably, D₂₁>D₂₃.
Removing the resist 27′ (see FIG. 3I).
Carrying out complementary etching of the layer 21, up to layer 22. This makes it possible to form a recess 21b in the layer 21. Next, by lamination, a polymer film 28 is deposited on the layer 24. See FIG. 3J. The polymer film 28 is of the same type as the film 18 described above.
Removing, by wet etching, the layer 22 of SiO₂: see FIG. 3K. This step makes it possible to form a through-aperture 20a.
Removing the polymer film 28: See FIG. 3L. A second microstructured substrate 20′ that has the structuring required to form the rear portion 2r of the enclosure is thus obtained. The second microstructured substrate 20′ extends, thicknesswise, between a second top side 20′ₛ, adjacent to the second upper layer 23, and a second bottom side 20′ᵢ, adjacent to the second lower layer 21.
A wafer 20p comprising an Si layer 20p2 with a thickness of 550 μm covered with a layer 20p1 of a polymer is then used as a handle wafer. The wafer is affixed to the second bottom side 20′ᵢ of the second substrate 20′ (see FIGS. 3M and 3N). In FIG. 3M, the second substrate has been flipped with respect to FIG. 3L.
Applying, by lamination, a polymer adhesive film 29′ to the second upper layer 23. The adhesive film may for example be an SINR film (SINR being a registered trademark—supplier Shin-Etsu MicroSi) with a thickness of 12 μm. An anneal is then carried out. See FIG. 3O.
Exposing the film 29′, so as to leave only a peripheral portion extending around the aperture 20a of the substrate 20′, then carrying out an anneal. See FIG. 3P.
Removing the handle 20p: FIG. 3Q, in which the second substrate has been flipped with respect to FIG. 3P. This step makes it possible to obtain the rear portion 2r of the enclosure, after assemblage by thermocompression bonding. The through-aperture 20a forms the rear portion 4r of the cavity 4. The assemblage step is described below, with reference to FIGS. 5A to 5C.

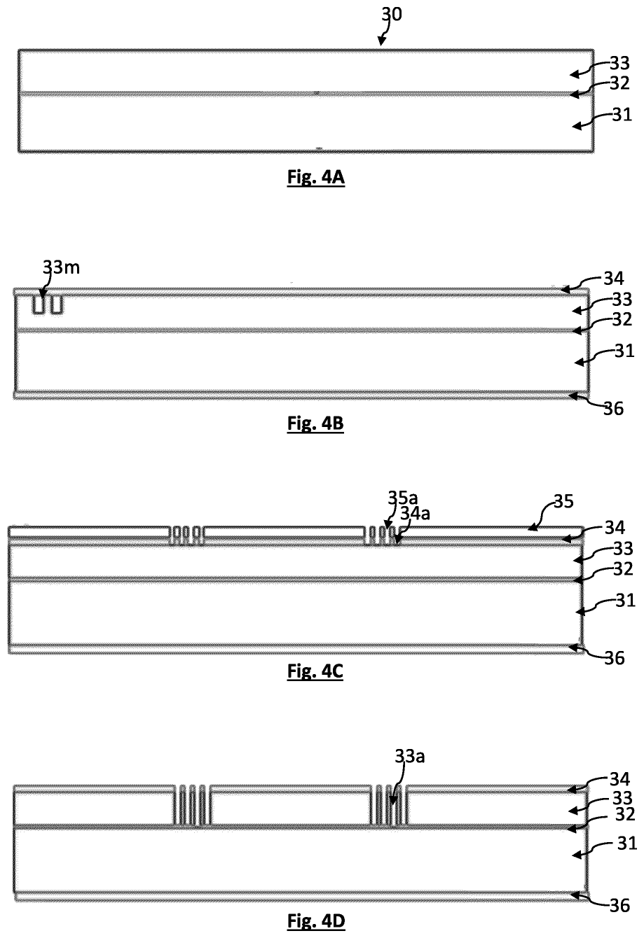

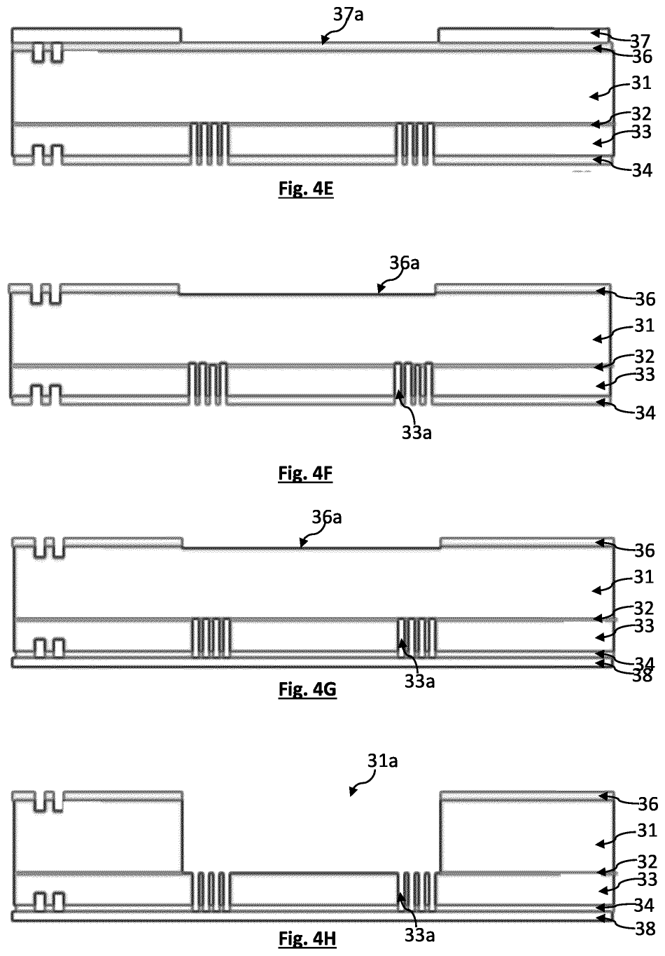

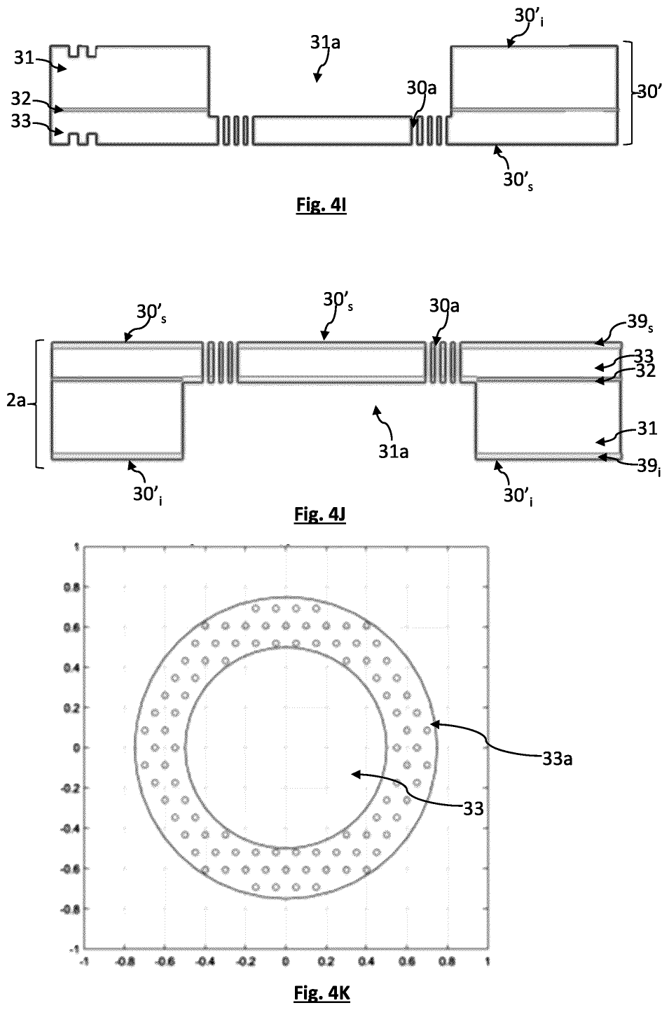

FIGS. 4A to 4J show the steps of processing of a third substrate 30, to form the front portion 2a of the enclosure of the device. A third substrate 30, comprising a third lower layer 31, a third intermediate layer 32 and a third upper layer 33 similar to the lower, intermediate and upper layers of the first and second substrates described above, respectively, is used. See FIG. 4A.

The steps of structuring of the third substrate 30 are, successively:
Forming reference points 33m on the third upper layer by laser engraving. These reference points allow alignment of photolithography masks. Next a layer 36 of SiO2, with a thickness between 3 μm and 5 μm, is deposited on the third lower layer 31, and a layer 34 of SiO2, with a thickness between 3 μm and 5 μm, is deposited on the third upper layer 33: see FIG. 4B.
Depositing a layer 35 of photoresist on the layer 34 of SiO2, then forming a pattern through exposure. The pattern defines apertures 35a in the resist layer 35. Next, the layer 34 is plasma etched so as to form apertures 34a in the layer 34. See FIG. 4C. The aim is to initiate the formation of through-apertures in the layer 33, with a view to forming the membrane 5 described with reference to FIG. 1.
Plasma etching the upper layer 33 so as to form apertures 33a in the latter, plumb with each aperture 34a resulting from the previous step. See FIG. 4D. The steps shown in FIGS. 4C and 4D are optional.
Depositing a layer 37 of photoresist on the layer 36, then forming a pattern through exposure. The pattern defines an aperture 37a. See FIG. 4E, in which the third substrate has been flipped with respect to FIG. 4D.
Plasma etching the layer 36, so as to form an aperture 36a in the layer 36, and then removing the resist 37. See FIG. 4F.
Depositing, by lamination, a polymer film 38 on the layer 34. See FIG. 4G. The film 38 is of the same type as the films 18 and 28 described above.
Plasma etching the lower layer 31 so as to form an aperture 31a in the latter, plumb with the aperture 36a resulting from the step described with reference to FIG. 4F. See FIG. 4H.
Removing the polymer film 38. See FIG. 4I. A third microstructured substrate 30′ that has the structuring required to form the front portion 2a of the enclosure is thus obtained. The third microstructured substrate 30′ extends, thicknesswise, between a third top side 30′ₛ, adjacent to the third upper layer 33, and a third bottom side 30′ᵢ, adjacent to the third lower layer 31.
Depositing a Ge—ZnS antireflection layer 39s, 39ᵢ comprising a thickness of 100 nm of Ge and of 1067 nm of ZnS on the third top side and the third bottom side of the substrate 30′, respectively. See FIG. 4J. This step makes it possible to obtain the front portion 2a of the enclosure 2 of the device, comprising the membrane.

FIG. 4K shows a top view of the substrate 30′: the through-apertures 30a, which correspond, after assemblage, to the apertures 5o of the membrane, may be seen. In this example, the through-apertures have a diameter of 30 μm, the spacing between two adjacent apertures being 100 μm. In FIG. 4K, the unit of each axis is millimetres.

In the embodiment shown in FIGS. 4A to 4K, the membrane comprises apertures and is set back from the contact face. The membrane bounds a hollow front portion of the cavity: the front portion of the cavity extends between the contact face and the membrane. According to one variant, the etching of the third lower layer 31 is such that, following the step shown in FIG. 4H, the membrane lies flush with the contact face. According to this variant, it is preferable for the membrane to not be apertured: it is intended to be placed in contact, or in quasi-contact, for example at less than 1 mm or less than 500 μm or less than 100 μm, from the sample.

FIGS. 5A to 5D show the steps of assemblage, by thermocompression bonding, allowing the enclosure 2 of the device shown in FIG. 1 to be formed, by:
assemblage of the rear portion 2r with the front portion 2a: the second top side 20′ₛ of the second substrate 20′ is adhesively bonded, by the polymer 29′, to the third top side 30′ of the third substrate 30′: see FIGS. 5A and 5B: a substrate 2ar is obtained;
assemblage of the cover 2c with the substrate 2ar: the second bottom side 20′ᵢ of the second substrate 20′ is adhesively bonded, by the polymer 19′, to the first bottom side 10′ᵢ of the first substrate 30′ (see FIGS. 5C and 5D): an assembled substrate forming the enclosure 2 of the device is obtained. FIG. 5D shows the main components of the enclosure, as described with reference to FIG. 1. The spaces for the transducer T, light source S and detector D have also been shown schematically.

Each assemblage is carried out, for example, by thermocompression bonding, by means of the polymer adhesive 19′, 39′. Other organic or inorganic adhesives may be used.

The order of the assemblage may be reversed.

The method described above may be replicated on the same substrate, in parallel, so as to simultaneously form a plurality of enclosures 2. A plurality of enclosures 2 that, after all the fabricating steps have been carried out, may be separated from one another using a pick-and-place process, is thus obtained. The bonding may be performed at the wafer level (wafer-to-wafer bonding), or die-to-wafer bonding or flip-chip (chip-to-chip) bonding may be used.

Using microfabrication processes makes it possible to obtain a compact device, compatible with integration into a nomadic object, a smart watch for example. The volume of the enclosure 2 may be of the order of a few tenths of a cm³. The process may be implemented using standard silicon substrates.

Using a polymer in the thermocompression bonding makes it possible to overcome difficulties associated with metal bonding, the yield of which is low and dependent on the surface finish of the assembled surfaces. According to alternatives, the assemblage of the three substrates may be carried out by Ti—Ti or Au—Au metal bonding. In this case, the portions intended to be assembled are metals.

The use of three independent substrates allows one of them to be modified, without affecting the fabrication of the others. For example, the first substrate, forming the cover, may be modified, while remaining compatible with the second and third substrates, forming the rear and front portions of the enclosure. In the same way, the configuration of the membrane (3^{rd} substrate) may be modified while remaining compatible with the first and second substrates, forming the cover and the rear portion of the enclosure.

Using three independent substrates also makes it possible to envisage parallel fabrication.

Although described with reference to SOI substrates, this corresponding to an advantageous configuration because each intermediate layer of insulator may be used as an etch-stop layer, it is conceivable to use other types of substrates (bulk substrates).

1. A method for fabricating an enclosure bounding a hollow cavity, the enclosure being configured to be applied against a sample to be analysed, the cavity being configured to extend between the sample and an acoustic transducer, the cavity opening onto a contact face intended to be applied against the sample, the enclosure comprising:
a contact aperture formed in the contact face, and opening into the cavity;
a membrane extending through the cavity, facing the contact face, so that all or part of the cavity lies between the membrane and a cover;
wherein the method comprises the following steps:
1) microstructuring a first substrate, so as to form the cover;
2) microstructuring a second substrate, so as to form a rear portion of the enclosure, bounding all or part of the cavity, between the membrane and the cover;
3) microstructuring a third substrate, so as to form a front portion of the enclosure, comprising the membrane;
4) assembling the cover to the rear portion of the enclosure, and the rear portion of the enclosure to the front portion of the enclosure.

2. The method according to claim 1, wherein the membrane divides the cavity into a rear portion of the cavity and into a front portion of the cavity, the front portion of the cavity opening onto the contact face, the membrane being placed between the front portion of the cavity and the rear portion of the cavity, wherein:
step 2) comprises forming the rear portion of the cavity;
step 3) comprises forming the front portion of the cavity.

3. The method according to claim 1, wherein step 1) comprises forming an acoustic channel through the cover, the acoustic channel being intended to connect the cavity to the acoustic transducer.

4. The method according to claim 1, wherein step 1) comprises forming a vent through the cover, the vent being intended to connect the cavity to a medium outside the latter.

5. The method according to claim 1, wherein step 1) comprises forming a detection channel through the cover, the detection channel being intended to connect the cavity to a temperature and/or humidity sensor.

6. The method according to claim 3, wherein:
the first substrate comprises a first upper layer, an insulating first intermediate layer, and a first lower layer;
step 1) comprises.
1i) etching the first lower layer to form at least one first lower aperture, the first intermediate layer acting as etch-stop layer;
1ii) etching the first upper layer to form at least one first upper aperture, the first intermediate layer acting as etch-stop layer;
1iii) removing the first intermediate layer, between each first lower aperture formed in substep 1i) and each first upper aperture formed in substep 1ii), respectively, so as to form a channel chosen from the acoustic channel, the vent or the detection channel.

7. The method according to claim 6, wherein the first intermediate layer is formed from an insulator, the first upper layer and the first lower layer being formed from a semiconductor.

8. The method according to claim 1, wherein:
the second substrate comprises a second upper layer, a second intermediate layer, and a second lower layer;
step 2) comprises the following substeps
2i) etching the second upper layer to form a second upper aperture, the second intermediate layer acting as etch-stop layer;
2ii) etching the second lower layer to form a second lower aperture, the second intermediate layer acting as etch-stop layer;
2iii) removing the second intermediate layer, between the second upper aperture formed in substep 2i) and the second lower aperture formed in substep 2ii), respectively, so as to form all or part of the cavity.

9. The method according to claim 8, wherein:
the second substrate lies parallel to a main plane;
in step 2i), the etching is carried out, through the second upper layer, according to an upper dimension, in the main plane;
in step 2ii), the etching is carried out, through the second lower layer, according to a lower dimension, in the main plane;
the lower dimension is greater than the upper dimension.

10. The method according to claim 8, wherein the thickness of the second lower layer is greater than the thickness of the second upper layer.

11. The method according to claim 8, wherein the second intermediate layer is formed from an insulator, the second upper layer and the second lower layer being formed from a semiconductor.

12. The method according to claim 8, wherein
the membrane divides the cavity into a rear portion of the cavity and into a front portion of the cavity, the front portion of the cavity opening onto the contact face, the membrane being placed between the front portion of the cavity and the rear portion of the cavity, wherein:
step 2) comprises forming the rear portion of the cavity;
step 3) comprises forming the front portion of the cavity.
wherein, in step 2iii), removing the second intermediate layer forms the rear portion of the cavity.

13. The method according to claim 1, wherein:
the third substrate comprises a third upper layer, a third intermediate layer, and a third lower layer;
step 3) comprises:
3i) etching the third lower layer, so as to form a front portion of the enclosure, the third intermediate layer acting as etch-stop layer, the third upper layer forming the membrane.

14. The method according to claim 13,
wherein the membrane divides the cavity into a rear portion of the cavity and into a front portion of the cavity, the front portion of the cavity opening onto the contact face, the membrane being placed between the front portion of the cavity and the rear portion of the cavity, wherein:
step 2) comprises forming the rear portion of the cavity;
step 3) comprises forming the front portion of the cavity.
wherein, in step 3i), etching the third lower layer forms the front portion of the cavity.

15. The method according to claim 1, wherein the membrane is passed through by apertures.

16. The method according to claim 13, wherein the membrane is passed through by apertures, wherein the method further comprises:
3ii) etching the third upper layer, the third intermediate layer acting as etch-stop layer, the etching of the third upper layer being configured to form a plurality of third apertures extending through the third upper layer;
3iii) removing the third intermediate layer, level with each third aperture resulting from substep 3ii), so that each third aperture is a through-aperture.

17. The method according to claim 1, wherein step 4) is carried out by thermocompression bonding.

18. An enclosure bounding a cavity, the enclosure being configured to be applied against a sample to be analysed, the cavity being configured to extend between the sample and an acoustic detector, the cavity opening onto a contact face configured to be applied against the sample, the enclosure comprising:
a contact aperture formed in the contact face, and opening into the cavity;
a membrane extending through the cavity, facing the contact face, so that all or part of the cavity lies between the membrane and a cover;
the enclosure being fabricated by implementing steps 1) to 4) of the method according to claim 1.

19. A device comprising an enclosure, bounding a cavity, the enclosure being configured to be applied against a sample to be analysed, the device comprising:
a contact face that opens into the cavity, and that is intended to be applied against the sample;
a light source, configured to emit pulsed or amplitude-modulated light through the enclosure, towards the contact face;
an acoustic transducer, connected to the cavity;
wherein the enclosure is an enclosure according to claim 18.
